(19) United States
(12) Patent Application Publication
(10) Pub. No.: US 2004/0152349 A1
(43) Pub. Date: Aug. 5, 2004

(54) Terminal pin

(76) Inventor: Wen-Hao Hsu, Lu Chou City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/353,997

(22) Filed: Jan. 30, 2003

(51) Int. Cl. H05K 1/00; H01R 12/00

(52) U.S. Cl. 439/78

(57) ABSTRACT

A terminal pin has one end mounted in a pin fastener. The, other end of the terminal pin has a contoured cover layer that is cut and rolled by a contoured cutting tool so that the terminal pin is formed into a contoured profile to provide improved solderability.

### BACKGROUND OF THE INVENTION

1. Field of the Invention

The invention relates to a terminal pin and, more particularly, to a terminal pin that has a contoured cover layer cut and rolled by a contoured cutting tool.

2. Description of the Related Art

A conventional terminal pin is formed either by soldering and then cutting, or by cutting and then soldering. The first processing way usually provides poor solderability due to natural oxidization. The second processing way wastes the solder that is removed in the cutting step.

Furthermore, the conventional terminal pin is cut by means of a flat-profiled cutting tool. Therefore, the terminal pin after being cut is planar in cross-section. The flat-profiled cutting tool cannot roll the terminal pin during cutting so that a solder layer formed over the terminal pin does not cover a section surface of the terminal pin. The section surface of the terminal pin is therefore exposed to the atmosphere and easily oxidizes, causing failure of a solderability test of the standard IEC68-2-69, performed after an aging test of the standard EA1364-52.

When the terminal pin is not bent parallel to a printed circuit board (PCB), it is usually connected to the PCB by insertion. When the terminal pin is bent to have a L-shape, it can be mounted on a surface of the PCB by surface mount technology (SMT).

Regardless of whether a wire or a lead frame is soldered before or after being cut, the “neat” section surface of the terminal pin is subject to the following situations. The section surface of the terminal pin is directly exposed to the atmosphere. Therefore, it easily oxidizes, which deteriorates the solderability and thus shortens the service life of the terminal pin. An excessive duration of soldering results in the formation of a solder point on the section surface of the terminal pin. If the peak portion of the solder point is long, then it requires an additional cutting process to remove it. An insufficient duration of soldering results in the formation of non-uniform solder on the section surface of the terminal pin, which possibly exposes and oxidizes the section surface of the terminal pin.

Thereafter, the terminal pin is wave-soldered or IR reflowed on the PCB. Since there may be tapered solder point or non-uniform solder on the section surface of the terminal pin, the bonding of the terminal pin to the PCB by insertion or surface mounting is not good, especially in surface mounting.

Referring to FIGS. 1-3, illustrating the conventional terminal pin connected to a coil of a transformer, a conventional terminal pin assembly 60 includes a body 61, a plurality of pin fasteners 62, and a plurality of terminal pins 63. The body 61 is I-shaped in cross-section. Each of the pin fasteners 62 is mounted on a bottom of the body 61 and outwardly protrudes therefrom. One end of each terminal pin 63 is fastened by a corresponding pin fastener 62, and the other end has a section surface 64 that is formed after being vertically cut by a flat-profiled cutting tool 65. If the duration of soldering is not sufficient, the unprotected section surface 64 of the terminal pin 63 is coated with a non-uniform solder layer. If the duration of soldering is excessive, the tapered solder point 66 is easily formed on the section surface 64 of the terminal pin 63.

The non-uniform solder results in the oxidation of the section surface 64 of the terminal pin 63, which deteriorates the solderability and causes de-wetting of the solder. If there is the solder point 66 on the section surface 64, this latter must undergo an additional cutting step to remove the unwanted portion of the solder.

### SUMMARY OF INVENTION

It is therefore one object of the invention to provide a terminal pin with improved solderability and prevent the de-wetting of the solder.

It is another object of the invention to provide a terminal pin that improves the bonding to a printed circuit board (PCB) either by insertion or surface mounting.

In order to achieve the above and other objectives, an improved terminal pin is provided. On end of the terminal pin of the invention is mounted in a pin fastener, and the other end has a cover layer over a section surface of the terminal pin for inserting through or surface mounting on the PCB. The section surface of the terminal pin is at least wider than the cover layer.

To provide a further understanding of the invention, the following detailed description illustrates embodiments and examples of the invention, this detailed description being provided only for illustration of the invention.

### BRIEF DESCRIPTION OF THE DRAWINGS

The drawings included herein provide a further understanding of the invention. A brief introduction of the drawings is as follows:

FIG. 1 is a perspective view of a conventional terminal pin assembly;

FIG. 2 is a side view of a conventional terminal pin assembly during cutting by means of a cutting tool;

FIG. 3 is a side view of a conventional terminal pin assembly;

FIG. 4 is a perspective view of a terminal pin assembly according to one embodiment of the invention;

FIG. 5 is a side view of a terminal pin assembly during cutting by means of a cutting tool according to one embodiment of the invention;

FIG. 6 is a perspective view of a terminal pin assembly during cutting by means of a cutting tool according to one embodiment of the invention;

FIG. 7 is a side view illustrating a terminal pin assembly mounted in a PCB according to one embodiment of the invention;

FIG. 8 is a side view illustrating a terminal pin assembly ready to be mounted in a PCB according to one embodiment of the invention;

FIG. 9 is a perspective view of a terminal pin assembly according to another embodiment of the invention; and

FIG. 10 is a perspective view of a terminal pin assembly according to another variant embodiment of the invention.

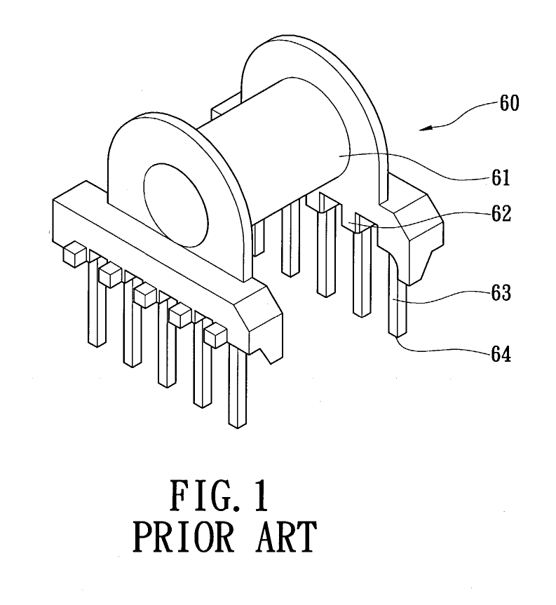

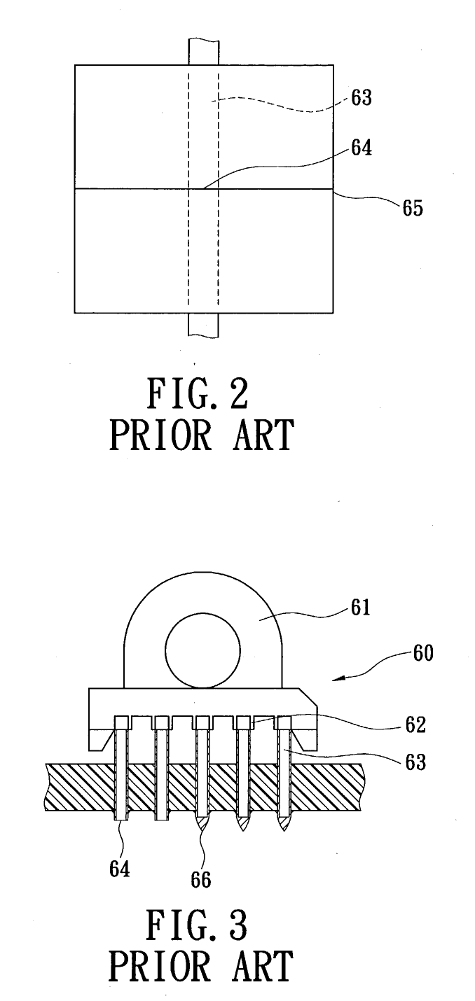

Annex 1 is a test report, made by ELECTRONICS TESTING CENTER, TAIWAN, which shows the respective solderabilities of a non-contoured terminal pin and of a contoured terminal pin after aging.

### DETAILED DESCRIPTION OF THE EMBODIMENTS

Wherever possible in the following description, like reference numerals will refer to like elements and parts unless otherwise illustrated.

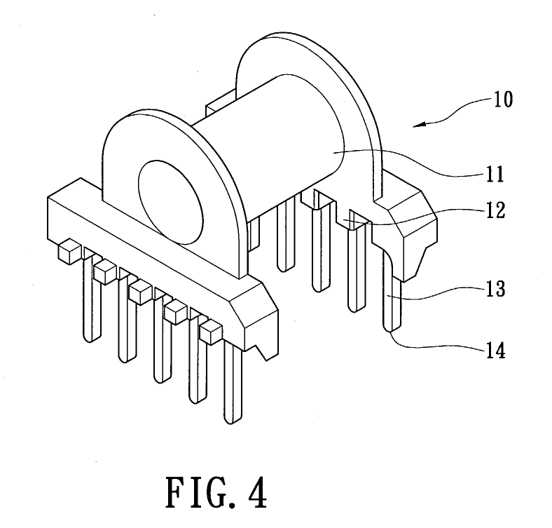

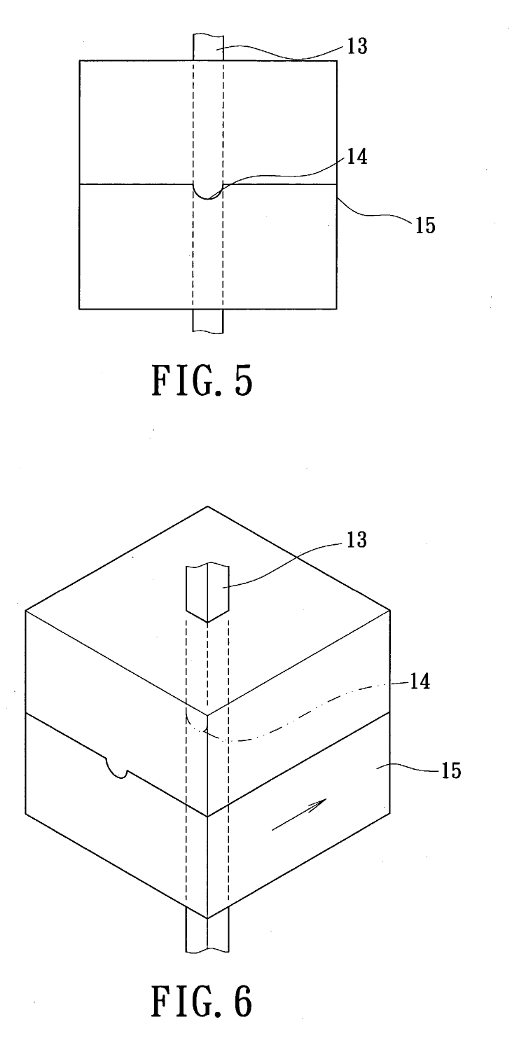

Referring to FIGS. 4-6, a terminal pin assembly 10 of the invention includes a body 11, a plurality of pin fasteners 12, and a plurality of terminal pins 13 each having a cover layer 14 over the section surface of the pins. The body 11 is I-shaped in cross-section. Each of the pin fasteners 12 is a raised portion on a bottom of the body 11 for respectively mounting a corresponding terminal pin 13. Each of the terminal pins 13 has a column-shaped body. One end of each terminal pin 13 is mounted in one corresponding pin fastener 12. The other end of each terminal pin 13 is covered with the cover layer 14 that may be rounded by a round-profiled cutting tool 15.

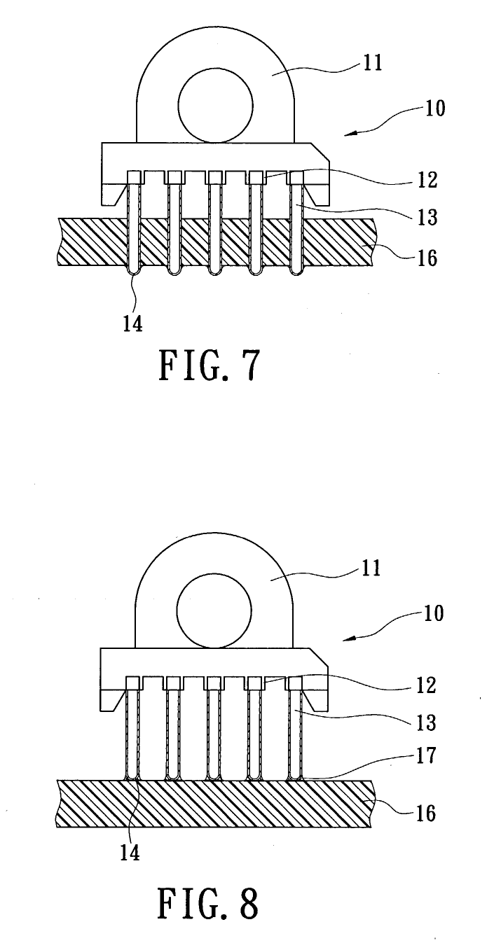

Referring to FIG. 7, the terminal pins 13 are inserted through the PCB 16. The rounded contour of the cover layer 14 on the tip of the terminal pin 13 helps insert the terminal pins 13 through the PCB 16.

Referring to FIG. 8, the terminal pins 13 are surface mounted to the PCB 16. A clearance 17 is formed between each round cover layer 14 and the PCB 16 for the solder of the cover layer 14 to be filled. A test report, made by ELECTRONICS TESTING CENTER, TAIWAN, shows the respective solderabilities of a non-contoured terminal pin and a contoured terminal pin after aging.

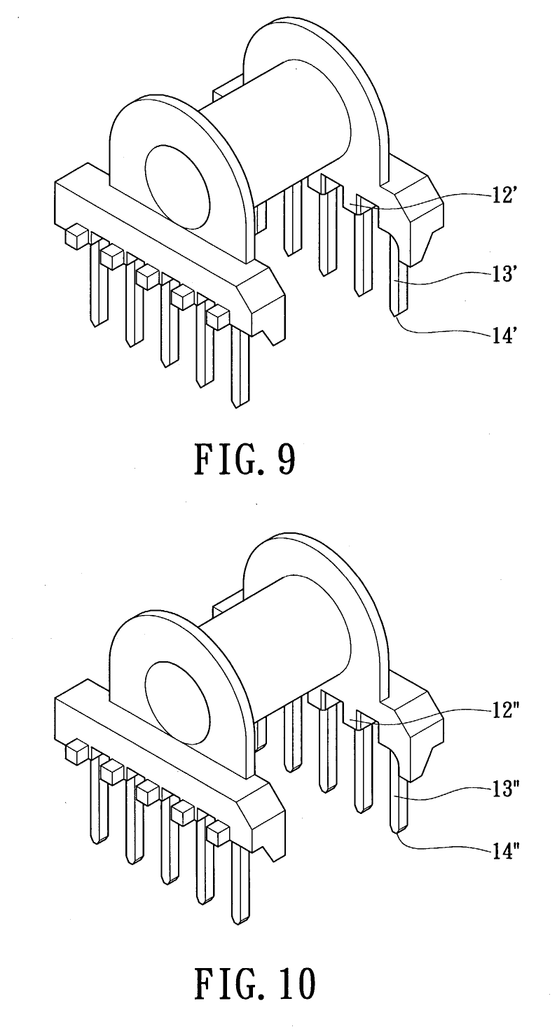

Referring to FIG. 9 which illustrates another embodiment of the invention, one end of a terminal pin 13′ is mounted in a pin fastener 12′, and the other end thereof has a tapered cover layer 14′.

Referring to FIG. 10, which illustrates another variant embodiment of the invention, one end of a terminal pin 13″ is mounted in a pin fastener 12″, and the other end thereof has a polygonal contoured cover layer 14″.

The terminal pin of the invention is characterized in that the terminal pin is cut by a contoured cutting tool so that a section surface of the terminal pin is blanketed by the solder.

By means of the cutting and rolling of the contoured cutting tool, the terminal pins are formed into a contoured profile, such as round, tapered or polygonal profiles, to provide an improved solderability and prevent the formation of solder points. Furthermore, the contoured profiles of the terminal pins are advantageous to the bonding between the terminal pins and the PCB, performed by insertion or surface mounting.

With the invention, the prior art problems, such as poor bonding to the PCB caused by the oxidation of the section surface of the terminal pin and the demand of a further cutting step for removing the excessive solder on the section surface of the terminal pins, are thereby overcome.

It should be apparent to those skilled in the art that the above description is only illustrative of specific embodiments and examples of the invention. The invention should therefore cover various modifications and variations made to the herein-described structure and operations of the invention, provided they fall within the scope of the invention as defined in the following appended claims.

What is claimed is:

1. A terminal pin, comprising a first end being mounted in a corresponding pin fastener, and a second end with a section surface having a cover layer thereon for inserting through or surface mounting on a printed circuit board (PCB), a section surface of the terminal pin being at least wider than the cover layer.

2. The terminal pin of claim 1, wherein the cover layer has a round profile.

3. The terminal pin of claim 1, wherein the cover layer has a tapered profile.

4. The terminal pin of claim 1, wherein the cover layer has a polygonal profile.
